(19) United States
(12) Patent Application Publication
(10) Pub. No.: US 2024/0168226 A1
(43) Pub. Date: May 23, 2024

(54) OPTICAL CIRCUIT BOARD AND OPTICAL COMPONENT MOUNTING STRUCTURE USING SAME

(71) Applicant: KYOCERA Corporation, Kyoto-shi, Kyoto (JP)

(72) Inventor: Shinya TOMOZAWA, Konan-shi (JP)

(73) Assignee: KYOCERA Corporation, Kyoto-shi, Kyoto (JP)

(21) Appl. No.: 18/552,990

(22) PCT Filed: Mar. 24, 2022
(86) PCT No.: PCT/JP2022/013802

§ 371 Date: Sep. 28, 2023

(30) Foreign Application Priority Data
Mar. 30, 2021 (JP) 2021-056546

(51) Int. Cl. G02B 6/122; G02B 6/132

(52) U.S. Cl. CPC G02B 6/122; G02B 6/132

(57) ABSTRACT

An optical circuit board includes a wiring board and an optical waveguide. The wiring board includes an upper surface including a mounting region for an optical component. The optical waveguide is located adjacent to the mounting region for the optical component on the wiring board and includes a lower cladding layer, a plurality of cores including a signal core and alignment cores sandwiching the signal core, and an upper cladding layer in order from an upper surface of the wiring board. The alignment core includes a first end surface proximate to the mounting region for the optical component, and the first end surface is inclined relative to the upper surface of the wiring board.

### TECHNICAL FIELD

The present invention relates to an optical circuit board and an optical component mounting structure using the same.

### BACKGROUND OF INVENTION

In recent years, optical fiber that can communicate large amounts of data at high speed has been used for information communication (e.g., Patent Document 1). Optical signals are transmitted and received between the optical fiber and an optical element (silicon photonics device).

### CITATION LIST

### Patent Literature

Patent Document 1: JP 6290742 B

### SUMMARY

### Solution to Problem

An optical circuit board includes a wiring board and an optical waveguide. The wiring board includes an upper surface including a mounting region for an optical component. The optical waveguide is located adjacent to the mounting region for the optical component on the wiring board and includes a lower cladding layer, a plurality of cores including a signal core and alignment cores sandwiching the signal core, and an upper cladding layer in order from the upper surface of the wiring board. Each of the alignment cores includes a first end surface proximate to the mounting region for the optical component, and the first end surface is inclined relative to the upper surface of the wiring board. According to the present disclosure, an optical component mounting structure includes the optical circuit board described above and an optical component.

According to the present disclosure, a method for manufacturing an optical circuit board includes obtaining a wiring board including an upper surface, the upper surface including an optical waveguide forming region and a mounting region for an optical component, a first conductor layer located on the upper surface between the optical waveguide forming region and the mounting region for the optical component, and a solder resist covering the first conductor layer; forming an optical waveguide precursor by sequentially layering a lower cladding layer, a plurality of cores including a signal core and alignment cores sandwiching the signal core, and an upper cladding layer across the optical waveguide forming region to a first upper surface of the solder resist, the optical waveguide precursor including a first end surface proximate to the mounting region for the optical component, the first end surface being inclined relative to the upper surface of the wiring board; and forming an optical waveguide by removing, in the optical waveguide precursor, a portion the signal core located on the first upper surface of the solder resist and a portion of the solder resist located under the signal core so that the signal core is along the upper surface of the wiring board.

### BRIEF DESCRIPTION OF THE DRAWINGS

FIG. 1A is a plan view illustrating an optical component mounting structure in which a silicon photonics device and an electronic component are mounted on an optical circuit board according to an embodiment of the present disclosure, and FIG. 1B is an enlarged illustration diagram for illustrating a cross section passing through a signal core in a region X illustrated in FIG. 1A.

FIG. 2 is a plan view of a region Y illustrated in FIG. 1B (excluding an upper cladding layer of the silicon photonics device and optical waveguide).

FIG. 3A is an illustration diagram for illustrating a cross section passing through an alignment core seen along a direction of an arrow A illustrated in FIG. 2, FIG. 3B is an illustration diagram for illustrating a cross section passing through the signal core when taken along a line B-B illustrated in FIG. 2, and FIG. 3C is an illustration diagram for illustrating a cross section when the optical waveguide illustrated in FIG. 3B includes a cavity.

FIGS. 4A to 4C are plan views of the vicinity of the region Y in each manufacturing step of the wiring board.

### DESCRIPTION OF EMBODIMENTS

In mounting an optical component such as a silicon photonics device on an optical circuit board, an active alignment with higher accuracy is adopted. The “active alignment” is a means for determining a mounting position of the optical component by irradiating an alignment core with light and moving and adjusting the optical component and the optical circuit board so that a peak of received light becomes maximum. However, a highly accurate active alignment is difficult to adopt for the optical circuit board of the related art due to its structure. That is, an end surface of the alignment core, which is an entrance and exit portion of light, is close to a surface of a wiring board, and efficient transmission and reception of light to and from a light source for alignment is difficult.

Thus, a demand for an optical circuit board that can adopt an active alignment in mounting an optical component such as a silicon photonics device and can mount the optical component with high accuracy is present.

According to the optical circuit board of the present disclosure, an optical component can be mounted with high accuracy. According to a method for manufacturing an optical circuit board according to the present disclosure, an optical waveguide continuity inspection can be easily performed.

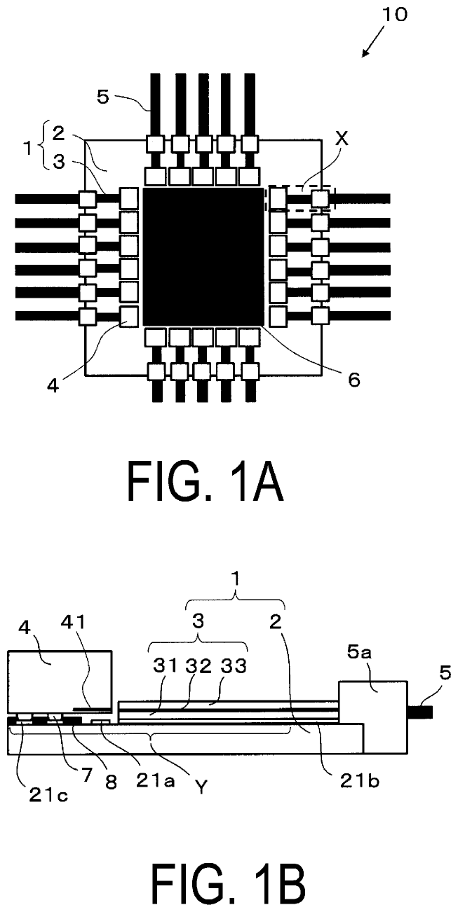

In an embodiment of the present disclosure, an optical circuit board will be described with reference to FIGS. 1A, 1B, 2, and 3A to 3C. FIG. 1A is a plan view illustrating an optical component mounting structure 10 in which a silicon photonics device (optical component) 4 is mounted on an optical circuit board 1 according to an embodiment of the present disclosure.

In an embodiment of the present disclosure, the optical circuit board 1 includes a wiring board 2 and an optical waveguide 3. The wiring board 2 included in the optical circuit board 1 according to an embodiment includes a wiring board typically used in optical circuit boards.

Although not specifically illustrated, such a wiring board 2 includes, for example, a core substrate and build-up layers layered on both surfaces of the core substrate. The core substrate is not particularly limited as long as the core substrate is made of a material having an insulation property. Examples of a material having an insulation property include resins such as an epoxy resin, a bismaleimide-triazine resin, a polyimide resin, and a polyphenylene ether resin. Two or more of these resins may be mixed and used. The core substrate usually includes a through hole conductor for electrically connecting the upper and lower surfaces of the core substrate.

The core substrate may contain a reinforcing material. Examples of the reinforcing material include insulation fabric materials such as glass fiber, glass non-woven fabric, aramid non-woven fabric, aramid fiber, and polyester fiber. Two or more types of reinforcing materials may be used in combination. Inorganic filler made of, for example, silica, barium sulfate, talc, clay, glass, calcium carbonate, titanium oxide, or the like may be dispersed in the core substrate.

The build-up layers have a structure in which insulating layers and conductor layers are alternately layered. A part of the outermost conductor layer (conductor layer located on the upper surface of the wiring board) includes a second conductor layer 21b on which the optical waveguide 3 is located. The conductor layer is a metal layer made of metal such as copper, for example. The insulating layer included in the build-up layer is not limited to any particular material as long as the insulating layer has the same insulation property as and/or similar insulation property to the core substrate. Examples of a material having an insulation property include resins such as an epoxy resin, a bismaleimide-triazine resin, a polyimide resin, and a polyphenylene ether resin. Two or more of these resins may be mixed and used.

When two or more insulating layers are present in the build-up layers, the insulating layers may be made of the same resin or may be made of different resins. The insulating layer included in the build-up layers and the core substrate may be made of the same resin or may be made of different resins. Each of the build-up layers usually includes a via hole conductor for electrically connecting the layers.

Inorganic filler made of, for example, silica, barium sulfate, talc, clay, glass, calcium carbonate, or titanium oxide may be dispersed in the insulating layer included in the build-up layers.

As illustrated in FIG. 1B, the optical waveguide 3 included in the optical circuit board 1 according to an embodiment is located on a surface of the second conductor layer 21b, which is a surface of the wiring board 2. FIG. 1B is an enlarged illustration diagram illustrating a cross section of a region X illustrated in FIG. 1A. The optical waveguide 3 has a structure in which a lower cladding layer 31, a core 32, and an upper cladding layer 33 are layered in this order from the second conductor layer 21b.

The lower cladding layer 31 included in the optical waveguide 3 is located on the surface of the wiring board 2, specifically on the surface of the second conductor layer 21b, which is located on a surface of an optical waveguide forming region R1 of the wiring board 2. The material forming the lower cladding layer 31 is not limited, and examples thereof include an epoxy resin and a silicone resin.

The upper cladding layer 33 included in the optical waveguide 3 is also made of the same material as and/or a similar material to the lower cladding layer 31. The lower cladding layer 31 and the upper cladding layer 33 may be made of the same material or may be made of different materials. The lower cladding layer 31 and the upper cladding layer 33 may have the same thickness or may have different thicknesses. For example, each of the lower cladding layer 31 and the upper cladding layer 33 has a thickness of from approximately 5 μm to approximately 150 μm.

The core 32 included in the optical waveguide 3 is a portion through which light that has entered the optical waveguide 3 propagates. The material forming the core 32 is not limited and is set as appropriate in consideration of, for example, light transmission properties, wavelength characteristics of light propagating therethrough, and the like. Examples of the material include an epoxy resin and a silicone resin. The core 32 has a thickness of from approximately 3 μm to approximately 50 μm, for example.

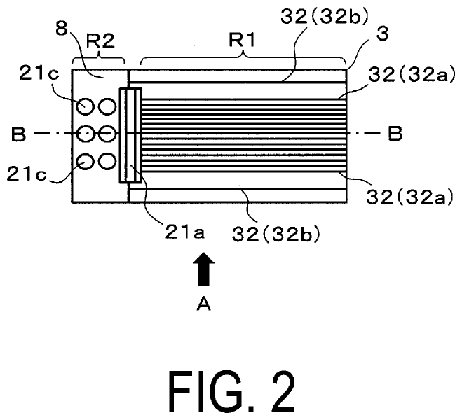

As illustrated in FIG. 2, one optical waveguide 3 includes a plurality of cores 32. FIG. 2 is a plan view of the region Y illustrated in FIG. 1B (excluding the upper cladding layer 33 of the silicon photonics device 4 and optical waveguide 3). The plurality of cores 32 include a signal core 32a and an alignment cores 32b. A plurality of signal cores 32a are present, and two alignment cores 32b are located to sandwich the plurality of signal cores 32a. The signal core 32a and the alignment core 32b may be made of the same material (resin) or may be made of different materials (resins).

The signal core 32a is located to face a silicon waveguide (Si waveguide) 41 included in the silicon photonics device 4 at one end portion of the optical waveguide 3. That is, the signal core is located such that an end surface of the Si waveguide 41 and an end surface of the signal core 32a of the optical waveguide 3 face each other. At this end portion, optical signals are transmitted and received between the signal core 32a and the Si waveguide 41.

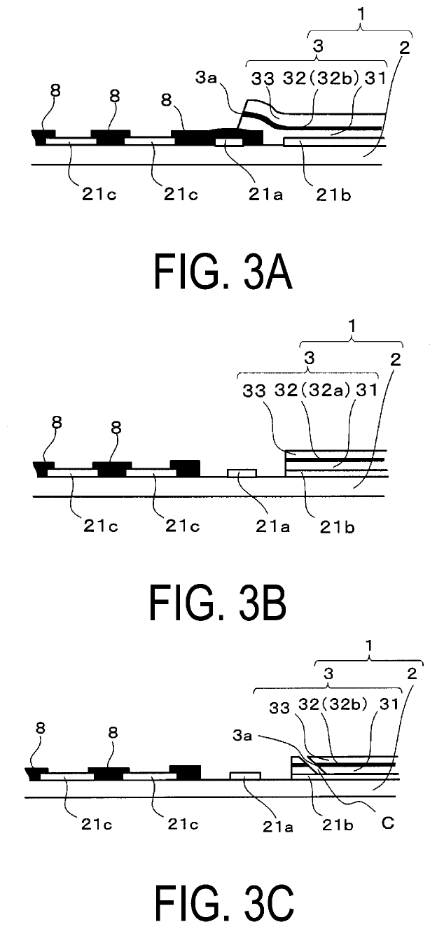

As illustrated in FIG. 3A, in the alignment core 32b, a first end surface 3a proximate to a mounting region R2 for the optical component 4 is inclined relative to the upper surface of the wiring board 2. FIG. 3A is an illustration diagram for illustrating a side as seen along a direction of an arrow A illustrated in FIG. 2. The structure in which the first end surface 3a is inclined relative to the upper surface of the wiring board 2 is not limited and may be, for example, a structure as illustrated in FIG. 3A. Specifically, on the upper surface of the wiring board 2, a first conductor layer 21a is located between the optical waveguide 3 and the mounting region R2 for the optical component 4, and a solder resist 8 is located to cover the first conductor layer 21a. A portion of the optical waveguide 3, which includes the first end surface 3a of the alignment core 32b, is located on the solder resist 8. For this reason, for example, an angle formed by the end surface of the signal core 32a and the upper surface of the wiring board 2 is different from an angle formed by the end surface (first end surface 3a) of the alignment core 32b and the upper surface of the wiring board 2. The solder resist 8 is made of a resin, and examples of the resin include an acrylic-modified epoxy resin.

When the first end surface 3a is inclined relative to the upper surface of the wiring board 2 as described above, light is easily transmitted and received between the light source and the alignment core 32b. For this reason, in mounting the optical component 4 on the optical circuit board 1 according to an embodiment, an active alignment can be adopted. As a result, the optical component 4 can be mounted on the optical circuit board 1 according to an embodiment with high accuracy. As illustrated in FIG. 3C, the alignment core 32b may have a structure in which a cavity C is provided in a portion proximate to the mounting region R2 for the optical component 4 and one surface constituting the cavity C is the first end surface 3a.

The angle of the first end surface 3a is not limited as long as the first end surface 3a is inclined relative to the upper surface of the wiring board 2. For example, the angle formed by the upper surface of the wiring board 2 and the first end surface 3a is 1° or greater and 30° or less. When the upper surface of the wiring board 2 and the first end surface 3a form such an angle, light is easily transmitted and received between the light source and the alignment core 32b. Accordingly, the function as the active alignment is sufficiently exhibited.

As illustrated in FIG. 3B, the signal core 32a is located to be parallel to the upper surface of the wiring board 2. FIG. 3B is an illustration diagram for illustrating a cross section taken along a line B-B illustrated in FIG. 2. As illustrated in FIG. 2, the solder resist 8 is not present under an end surface of the signal core 32a proximate to the mounting region for the optical component 4.

By the signal core 32a being located to be parallel to the upper surface of the wiring board 2, optical signals are efficiently transmitted and received to and from the optical component 4 to be mounted. In the present description, “parallel” is not limited to complete parallel. “Parallel” is defined even in the case of having an inclination of several degrees (for example, 5° or less) relative to the upper surface of the wiring board 2.

A method for manufacturing the optical circuit board 1 according to an embodiment is not particularly limited as long as the optical circuit board 1 having the structure as described above can be manufactured. A method for manufacturing an optical circuit board according to an embodiment of the present disclosure includes following steps (a) to (c).
Step (a): a step of obtaining a wiring board including an upper surface, which includes an optical waveguide forming region and a mounting region for an optical component, a first conductor layer located on the upper surface between the optical waveguide forming region and the mounting region for the optical component, and a solder resist covering the first conductor layer.
Step (b): a step of forming an optical waveguide precursor by sequentially layering a lower cladding layer, a plurality of cores including a signal core and alignment cores sandwiching the signal core, and an upper cladding layer across the optical waveguide forming region to a first upper surface of the solder resist so that a first end surface of the optical waveguide precursor proximate to the mounting region for the optical component is inclined relative to the upper surface of the wiring board.
Step (c): a step of forming an optical waveguide by removing, in the optical waveguide precursor, the signal core located on the first upper surface of the solder resist and the solder resist located under the signal core so that the signal core is along the upper surface of the wiring board.

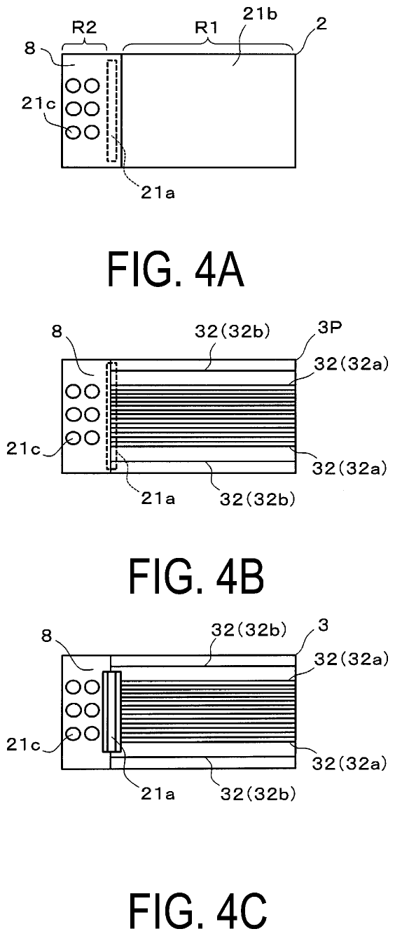

In the step (a), as illustrated in FIG. 4A, a wiring board 2 is prepared. On an upper surface of the wiring board 2, an optical waveguide forming region R1, a mounting region R2 for an optical component 4, a first conductor layer 21a located between the optical waveguide forming region R1 and the mounting region R2 for the optical component 4, a second conductor layer 21b located in the optical waveguide forming region R1, electrodes 21c located in the mounting region R2, and a solder resist 8 covering the mounting region R2 and the first conductor layer 21a. The conductor layers such as the first conductor layer 21a included in the wiring board 2 are made by metal plating such as copper plating or a metal foil such as a copper foil. The electrode 21c is located in an opening of the solder resist 8. The solder resist 8 is obtained, for example, by using a sheet made of the resin described above and performing exposure, development, and the like.

In the step (b), as illustrated in FIG. 4B, on the upper surface of the obtained wiring board 2, an optical waveguide precursor 3P is formed across the optical waveguide forming region R1 to a first upper surface of the solder resist 8 on the first conductor layer 21a. The optical waveguide precursor 3P is obtained by sequentially layering a lower cladding layer 31, a plurality of cores 32 including a signal core 32a and an alignment core 32b, and an upper cladding layer 33.

Specifically, the lower cladding layer 31, the plurality of cores 32, and the upper cladding layer 33 are obtained by using a sheet made of the resin described above and performing exposure, development, and the like. For the signal core 32a and the alignment core 32b, sheets made of the same resin may be used, or sheets made of different resins may be used.

In the optical waveguide precursor 3P, end surfaces of the respective cores 32 proximate to the mounting region R2 for the optical component 4 including a first end surface 3a of the alignment core 32b are located on the first upper surface of the solder resist 8 on the first conductor layer 21a. For this reason, as illustrated in FIG. 3A, the first end surface 3a of the alignment core 32b is inclined relative to the upper surface of the wiring board 2. An angle formed between the upper surface of the wiring board 2 and the first end surface 3a is as described above, and a detailed description thereof will be omitted.

In the step (b), an end surface of the signal core 32a proximate to the mounting region R2 is also inclined relative to the upper surface of the wiring board 2, as to the first end surface 3a of the alignment core 32b. For this reason, in a state of the signal core 32a between the step (b) and the step (c) described below, light is easily transmitted and received between the end surface proximate to the mounting region R2 and a light source. As a result, the optical waveguide continuity inspection can be easily performed in the manufacturing steps of the optical circuit board.

As described above, after the step (step (b)) of forming the optical waveguide precursor 3P, a step of inspecting optical continuity between an end surface of the signal core 32a proximate to the mounting region R2 and an end surface of the signal core 32a opposite to the mounting region R2 may be further included.

In the step (c), as illustrated in FIG. 4C, in the optical waveguide precursor 3P, a portion of the signal core 32a located on the first upper surface of the solder resist 8 and a portion of the solder resist 8 located under the signal core 32a are removed. Specifically, as illustrated in FIG. 2, the first conductor layer 21a located under the signal core 32a may be exposed from the solder resist 8, in a plan view. The signal core 32a and the solder resist 8 located under the signal core 32a are removed by, for example, laser processing.

By removing the portion of the signal core 32a located on the first upper surface of the solder resist 8 and the portion of the solder resist 8 located under the signal core 32a, the signal core 32a becomes only a portion along (parallel to) the upper surface of the wiring board 2. As a result, the optical waveguide 3 is formed on the upper surface of the wiring board 2. In the manner described above, the optical circuit board 1 according to an embodiment is obtained.

An optical component mounting structure of the present disclosure will be described. According to an embodiment of the present disclosure, the optical component mounting structure 10 has a structure in which the silicon photonics device 4 and an electronic component 6 are mounted on the optical circuit board 1 according to an embodiment. Examples of the electronic component 6 include an application specific integrated circuit (ASIC) and a driver IC.

As illustrated in FIG. 1B, the silicon photonics device 4 is electrically connected via a solder 7 to the electrode 21c located in the mounting region for an optical component of the wiring board 2. The electrode 21c is a part of the conductor layer located on the upper surface of the wiring board 2 and is located to be exposed from the opening of the solder resist 8.

The silicon photonics device 4 is one type of optical waveguide including, for example, a core made of silicon (Si) and a cladding made of silicon dioxide (SiO₂). The silicon photonics device 4 includes the Si waveguide 41 as described above and further includes a passivation film, a light source, and a photodetector (not illustrated). As described above, the Si waveguide 41 is located to face the signal core 32a included in the optical waveguide 3 at one end portion of the optical waveguide 3.

For example, an electrical signal from the wiring board 2 propagates to the light source included in the silicon photonics device 4 via the solder 7. The light source emits light upon receiving the electrical signal thus propagated. The optical signal of the emitted light propagates to an optical fiber 5 connected via an optical connector 5a, via a Si waveguide 41a for signal propagation and the signal core 32a of the optical waveguide 3.

### REFERENCE SIGNS

1 Optical circuit board
2 Wiring board
21a First conductor layer
21b Second conductor layer
21c Electrode
3 Optical waveguide
31 Lower cladding layer
32 Core
32a Signal core
32b Alignment core
33 Upper cladding layer
3a First end surface
4 Silicon photonics device (optical component)
41 Silicon waveguide (Si waveguide)
5 Optical fiber
5a Optical connector
6 Electronic component
7 Solder
8 Solder resist
10 Optical component mounting structure
R1 Optical waveguide forming region
R2 Mounting region
C Cavity

1. An optical circuit board comprising:
a wiring board; and
an optical waveguide,
wherein the wiring board comprises an upper surface comprising a mounting region for an optical component,
wherein the optical waveguide is located adjacent to the mounting region for the optical component on the wiring board and comprises a lower cladding layer, a plurality of cores comprising a signal core and alignment cores sandwiching the signal core, and an upper cladding layer in order from the upper surface of the wiring board,
wherein each of the alignment cores comprises a first end surface proximate to the mounting region for the optical component, and
wherein the first end surface is inclined relative to the upper surface of the wiring board.

2. The optical circuit board according to claim 1, wherein a first conductor layer located between the optical waveguide and the mounting region for the optical component and a solder resist covering the first conductor layer are provided on the upper surface of the wiring board, and
wherein, of the optical waveguide, a portion comprising the first end surface of each of the alignment cores is located on the solder resist, and the portion comprising the first end surface is inclined to be away from the upper surface of the wiring board as approaching the first end surface.

3. The optical circuit board according to claim 1, wherein each of the alignment cores comprises a cavity, and one surface constituting the cavity is the first end surface.

4. The optical circuit board according to claim 1, wherein the wiring board comprises a second conductor layer on the upper surface, and
wherein the optical waveguide is located on the second conductor layer.

5. An optical component mounting structure comprising the optical circuit board according to claim 1 and an optical component.

6. The optical component mounting structure according to claim 5, wherein the optical component is a silicon photonics device, and the silicon photonics device comprises a silicon waveguide, and
wherein the silicon waveguide is located to face the signal core.

7. A method for manufacturing an optical circuit board, the method comprising:
obtaining a wiring board comprising an upper surface, the upper surface comprising an optical waveguide forming region and a mounting region for an optical component, a first conductor layer located on the upper surface between the optical waveguide forming region and the mounting region for the optical component, and a solder resist covering the first conductor layer;
forming an optical waveguide precursor by sequentially layering a lower cladding layer, a plurality of cores comprising a signal core and alignment cores sandwiching the signal core, and an upper cladding layer across the optical waveguide forming region to a first upper surface of the solder resist, the optical waveguide precursor comprising at least a first end surface of each of the alignment core proximate to the mounting region for the optical component, the first end surface being inclined relative to the upper surface of the wiring board; and
forming an optical waveguide by removing at least a portion of the signal core in the optical waveguide precursor located on the first upper surface of the solder resist and leaving a portion of the optical waveguide precursor located on the first upper surface of the solder resist, the portion of the optical waveguide precursor comprising the alignment cores.

8. The method according to claim 7, further comprising, after the forming of the optical waveguide precursor, performing an optical continuity inspection between an end surface of the signal core proximate to the mounting region and an end surface of the signal core opposite to the mounting region.
